(19) United States
(12) Patent Application Publication
(10) Pub. No.: US 2023/0203245 A1
(43) Pub. Date: Jun. 29, 2023

(54) LIQUID CRYSTAL POLYMER RESIN COMPOSITION, METHOD FOR PRODUCING SAME, AND CARRIER FOR TRANSPORTING SEMICONDUCTORS

(71) Applicant: SUMITOMO CHEMICAL COMPANY, LIMITED, Tokyo (JP)

(72) Inventor: Hidenori SOMA, Sakura-shi (JP)

(21) Appl. No.: 17/926,761

(22) PCT Filed: Apr. 7, 2021
(86) PCT No.: PCT/JP2021/014783

§ 371 Date: Nov. 21, 2022

(30) Foreign Application Priority Data
May 26, 2020 (JP) 2020-091374

(51) Int. Cl. C08G 63/60; C08G 63/87; C08K 7/06; C08K 3/04; C08J 3/20

(52) U.S. Cl. CPC C08G 63/605; C08G 63/87; C08K 7/06; C08K 3/04; C08J 3/201; C08K 2201/001; C08J 2367/04; H01L 21/6773

(57) ABSTRACT

A liquid crystal polymer resin composition is provided containing a component (A) liquid crystal polymer, a component (B′) carbon fiber having a weight-average fiber length of less than 150 μm, and a component (C) carbon precursor having a volume resistivity of 10² to 10¹⁰ Ω·cm, in which a content of the component (B′) is 10 to 30 parts by mass with respect to 100 parts by mass of the component (A), a content of the component (C) is 5 to 35 parts by mass with respect to 100 parts by mass of the component (A), and a content of a total of the component (B) and the component (C) is 25 to 60 parts by mass with respect to 100 parts by mass of the component (A).

### TECHNICAL FIELD

The present invention relates to a liquid crystal polymer resin composition, a method for producing therefor, and a semiconductor conveyance carrier.

Priority is claimed on Japanese Patent Application No. 2020-091374, filed May 26, 2020, the content of which is incorporated herein by reference.

### BACKGROUND ART

A semiconductive resin composition obtained by dispersing a conductive filling material in a thermoplastic resin such as polybutylene terephthalate, polycarbonate, or a polyether ether ketone has excellent antistatic, dust adsorption-preventing, electromagnetic wave-shielding properties, and the like. Utilizing these properties, a semiconductive resin composition is used in the use application of a semiconductor conveyance carrier for conveying or storing semiconductor wafers, semiconductor elements, and the like (for example. Patent Document 1).

On the other hand, a molded body obtained from a liquid crystal polymer is used as a material for forming various electronic components since it has high hardness, high heat resistance, and high dimensional accuracy.

### CITATION LIST

### Patent Document

### [Patent Document 1]

Japanese Unexamined Patent Application, First Publication No. 2002-121402

### SUMMARY OF INVENTION

### Technical Problem

Therefore, a semiconductive resin composition obtained by dispersing a conductive filling material in a liquid crystal polymer can be expected to be used for the use application of a semiconductor conveyance carrier having high hardness and high heat resistance. The semiconductor conveyance carrier is required to have a proper surface resistance value in an electrostatic diffusion region (International Electrotechnical Commission (JEC) 61340) of 1.0×10⁵ to 1.0×10¹¹Ω. In addition, the semiconductor conveyance carrier is often repeatedly used by sticking a strongly adhesive tagging tape for display on the semiconductor conveyance carrier and peeling it off.

However, among the molded bodies obtained from the liquid crystal polymer resin composition in the related art, in a molded body that exhibits a proper surface resistance value in an electrostatic diffusion region, the skin layer on the surface is peeled off when the strongly adhesive tagging tape is peeled off. That is, a large number of molded bodies obtained from the liquid crystal polymer resin compositions in the related art have a problem in terms of tape peelability. On the contrary, ones having excellent tape peelability do not exhibit a proper surface resistance value in an electrostatic diffusion region.

The present invention has been made in consideration of the above circumstances, and an object of the present invention is to provide a liquid crystal polymer resin composition that enables the molding of a molded body having a proper surface resistance value in an electrostatic diffusion region and excellent tape peelability, and a method for producing therefor, as well as a semiconductor conveyance carrier.

### Solution to Problem

In order to achieve the above-described object, the present invention employs the following configurations.

[1] A liquid crystal polymer resin composition comprising the following component (A), component (B′), and component (C):

(A) liquid crystal polymer;

(B′) carbon fiber having a weight-average fiber length of less than 150 μm; and

(C) carbon precursor having a volume resistivity of 10² to 10¹⁰ Ω·cm,

in which a content of the component (B′) is 10 to 30 parts by mass with respect to 100 parts by mass of the component (A),

a content of the component (C) is 5 to 35 parts by mass with respect to 100 parts by mass of the component (A), and

a content of a total of the component (B′) and the component (C) is 25 to 60 parts by mass with respect to 100 parts by mass of the component (A).

[2] The liquid crystal polymer resin composition according to [I], further comprising a component (D) conductive carbon black, in which a content of a total of the component (B′), the component (C), and the component (D) is 25 to 60 parts by mass with respect to 100 parts by mass of the component (A).

[3] A semiconductor conveyance carrier including a main body part made of the liquid crystal polymer resin composition according to [1] or [2].

[4] A method for producing a liquid crystal polymer resin composition, the method including:

subjecting the following component (A), component (B), and component (C) to melt kneading:

(A) liquid crystal polymer,

(B) carbon fiber having a weight-average fiber length of less than 3,000 μm, and

(C) carbon precursor having a volume resistivity of 10² to 10¹⁰ Ω·cm,

in which a compounding amount of the component (B) is 10 to 30 parts by mass with respect to 100 parts by mass of the component (A),

a compounding amount of the component (C) is 5 to 35 parts by mass with respect to 100 parts by mass of the component (A), and

a compounding amount of a total of the component (B) and the component (C) is 25 to 60 parts by mass with respect to 100 parts by mass of the component (A).

### Advantageous Effects of Invention

According to the present invention, it is possible to provide a liquid crystal polymer resin composition that enables the molding of a molded body having a proper surface resistance value in an electrostatic diffusion region and excellent tape peelability, and a method for producing therefor, as well as a semiconductor conveyance carrier.

### BRIEF DESCRIPTION OF DRAWINGS

FIG. 1 is a perspective view schematically showing an example of a semiconductor conveyance carrier according to the present invention.

### DESCRIPTION OF EMBODIMENTS

<Liquid Crystal Polymer Resin Composition>

A liquid crystal polymer resin composition according to the present embodiment comprises the following component (A), component (B′), and component (C).

(A) Liquid Crystal Polymer, (B′) Carbon Fiber Having a Weight-Average Fiber Length of Less than 150 μm, (C) Carbon Precursor Having a Volume Resistivity of 10² to 10¹⁰ Ω·cm

(A) Liquid Crystal Polymer

In the present embodiment, the liquid crystal polymer resin composition comprises the component (A) liquid crystal polymer. The liquid crystal polymer (LCP) refers to a thermoplastic resin having a liquid crystal-like property in which molecular straight chains are regularly aligned in a melted state. It is preferable that even the liquid crystal polymer resin composition comprising a liquid crystal polymer (LCP) exhibits liquid crystal properties in a melted state, where a liquid crystal polymer resin composition that is melted at a temperature of 450° C. or lower is preferable. Since the liquid crystal polymer resin composition comprises a liquid crystal polymer, it has high hardness, high heat resistance, and high dimensional accuracy.

The liquid crystal polymer (LCP) that is used in the present embodiment may be a liquid crystal polyester, a liquid crystal polyester amide, a liquid crystal polyester ether, a liquid crystal polyester carbonate, or a liquid crystal polyester imide. The liquid crystal polymer (LCP) that is used in the present embodiment is preferably a liquid crystal polyester, and it is particularly preferably a fully aromatic liquid crystal polyester formed of only an aromatic compound as a raw material monomer.

Typical examples of the liquid crystal polyester that is used in the present embodiment include ones obtained by polymerizing (polycondensing) an aromatic hydroxycarboxylic acid, an aromatic dicarboxylic acid, and at least one compound selected from the group consisting of an aromatic diol, an aromatic hydroxylamine, and an aromatic diamine, ones obtained by polymerizing a plurality of kinds of aromatic hydroxycarboxylic acids, ones obtained by polymerizing an aromatic dicarboxylic acid and at least one compound selected from the group consisting of an aromatic diol, an aromatic hydroxylamine, and an aromatic diamine, and ones obtained by polymerizing polyester such as polyethylene terephthalate and an aromatic hydroxycarboxylic acid. Here, regarding the aromatic hydroxycarboxylic acid, the aromatic dicarboxylic acid, the aromatic diol, the aromatic hydroxyamine, and the aromatic diamine, some or the all may be each independently replaced with a polymerizable derivative thereof and used.

Examples of the polymerizable derivative of the compound having a carboxyl group, such as an aromatic hydroxycarboxylic acid or an aromatic dicarboxylic acid include ones (esters) obtained by converting a carboxyl group into an alkoxycarbonyl group or an aryloxycarbonyl group, ones (acid halides) obtained by converting a carboxyl group into a haloformyl group, and ones (acid anhydrides) obtained by converting a carboxyl group into an acyloxycarbonyl group. Examples of the polymerizable derivative of the compound having a hydroxyl group, such as an aromatic hydroxycarboxylic acid, an aromatic diol, or an aromatic hydroxyamine, include ones (acylated products) obtained by acylating a hydroxyl group to convert it into an acyloxyl group. Examples of the polymerizable derivative of the compound having an amino group, such as an aromatic hydroxyamine or an aromatic diamine, include ones (acylated product) obtained by acylating an amino group to convert it into an acylamino group.

The liquid crystal polyester that is used in the present embodiment preferably has a repeating unit represented by Formula (1) (hereinafter, may be referred to as a “repeating unit (1)”), and more preferably has the repeating unit (1), a repeating unit represented by Formula (2) (hereinafter, may be referred to as a “repeating unit (2)”), and a repeating unit represented by Formula (3) (hereinafter, may be referred to as a “repeating unit (3)”.

—O-Ar¹-CO— (1)

—CO-Ar²-CO— (2)

—X-Ar³-Y— (3)

(In Formulae (1) to (3), Ar¹ represents a phenylene group, a naphthylene group, or a biphenylylene group, and Ar² and Ar³ each independently represents a phenylene group, a naphthylene group, a biphenylene group, a group represented by Formula (4). X and Y each independently represents an oxygen atom or an imino group. A hydrogen atom in the group represented by Ar¹, Ar², and Ar³ may be each independently substituted with a halogen atom, an alkyl group, or an aryl group.)

-Ar⁴-Z-Ar⁵- (4)

(In Formula (4). Ar⁴ and Ar⁵ each independently represents a phenylene group or a naphthylene group. Z represents an oxygen atom, a sulfur atom, a carbonyl group, a sulfonyl group, or an alkylidene group.)

The liquid crystal polyester that is used in the present embodiment includes the repeating unit (1), the repeating unit (2), or the repeating unit (3), where it is preferable that the content proportion of the repeating unit (1) be 30% by mole or more and 100% by mole or less with respect to the total amount of the repeating unit (1), the repeating unit (2), or the repeating unit (3), the content proportion of the repeating unit (2) be 0% by mole or more and 35% by mole or less with respect to the total amount of the repeating unit (1), the repeating unit (2), or the repeating unit (3), and the content proportion of the repeating unit (3) be 0% by mole or more and 35% by mole or less with respect to the total amount of the repeating unit (1), the repeating unit (2), or the repeating unit (3).

Examples of the halogen atom include a fluorine atom, a chlorine atom, a bromine atom, and an iodine atom. Examples of the alkyl group include a methyl group, an ethyl group, an n-propyl group, an isopropyl group, an n-butyl group, an isobutyl group, an s-butyl group, a t-butyl group, an n-hexyl group, a 2-ethylhexyl group, an n-octyl group, and an n-decyl group, where the number of carbon atoms thereof is preferably 1 to 10. Examples of the aryl group include a phenyl group, an o-tolyl group, an m-tolyl group, a p-tolyl group, a 1-naphthyl group, and a 2-naphthyl group, where the number of carbon atoms thereof is preferably 6 to 20. When the above-described hydrogen atom is substituted with this group, the number of these groups is preferably 2 or less and more preferably 1 or less, independently for each group represented by Ar¹, Ar², or Ar³.

Examples of the alkylidene group include a methylene group, an ethylidene group, an isopropylidene group, an n-butylidene group, and a 2-ethylhexylidene group, where the number of carbon atoms thereof is preferably 1 to 10.

The repeating unit (1) is a repeating unit derived from a predetermined aromatic hydroxycarboxylic acid. Examples of the preferred repeating unit (1) include a repeating unit in which Ar¹ is a p-phenylene group (a repeating unit derived from p-hydroxybenzoic acid) and a repeating unit in which Ar¹ is a 2,6-naphthylene group (a repeating unit derived from 6-hydroxy-2-naphthoic acid).

It is to be noted that in the present specification, “derived” means that a chemical structure of a functional group that contributes to polymerization changes for the polymerization of the raw material monomer, and no other structural change occurs.

The repeating unit (2) is a repeating unit derived from a predetermined aromatic dicarboxylic acid. Examples of the preferred repeating unit (2) include a repeating unit in which Ar² is a p-phenylene group (a repeating unit derived from terephthalic acid), a repeating unit in which Ar² is an m-phenylene group (a repeating unit derived from isophthalic acid), a repeating unit in which Ar² is a 2,6-naphthylene group (a repeating unit derived from 2,6-naphthalenedicarboxylic acid), and a repeating unit in which Ar² is a diphenylether-4,4′-diyl group (a repeating unit derived from a diphenylether-4,4′-dicarboxylic acid).

The repeating unit (3) is a repeating unit derived from a predetermined aromatic diol, aromatic hydroxylamine, or aromatic diamine. Examples of the preferred repeating unit (3) include a repeating unit in which Ar³ is a p-phenylene group (a repeating unit derived from hydroquinone, p-aminophenol, or p-phenylenediamine) and a repeating unit in which Ar³ is a 4,4′-biphenylylene group (a repeating unit derived from 4,4′-dihydroxybiphenyl, 4-amino-4′-hydroxybiphenyl, or 4,4′-diaminobiphenyl).

The content proportion of the repeating unit (1) is preferably 30% by mole or more and 100% by mole or less, more preferably 30% by mole or more and 80% by mole or less, still more preferably 40% by mole or more and 70% by mole or less, and particularly preferably 45% by mole or more and 65% by mole or less, with respect to the total amount (a value obtained by dividing a mass of each repeating unit constituting the liquid crystal polymer by the formula amount of each repeating unit to determine an amount (in terms of mole) equivalent to the substance amount of each repeating unit and summing the determined amounts) of all repeating units.

The content proportion of the repeating unit (2) is preferably 0% by mole or more and 35% by mole or less, more preferably 10% by mole or more and 35% by mole or less, still more preferably 15% by mole or more and 30% by mole, and particularly preferably 17.5% by mole or more and 27.5% by mole or less, with respect to the total amount of all repeating units.

The content proportion of the repeating unit (3) is preferably 0% by mole or more and 35% by mole or less, more preferably 10% by mole or more and 35% by mole or less, still more preferably 15% by mole or more and 30% by mole, and particularly preferably 17.5% by mole or more and 27.5% by mole or less, with respect to the total amount of all repeating units.

The sum of the content proportion of the repeating unit (1) of the liquid crystal polyester, the content proportion of the repeating unit (2) of the liquid crystal polyester, and the content proportion of the repeating unit (3) of the liquid crystal polyester does not exceed 100% by mole.

The higher the content proportion of the repeating unit (1) is, the more easily the melt fluidity, the heat resistance, or the hardness and rigidity tend to improve; however, when it is too high, the melt temperature and the melt viscosity tend to easily increase, and the temperature required for molding easily tends to increase.

The ratio of the content of the repeating unit (2) to the content of the repeating unit (3), which is represented by [the content of the repeating unit (2)]/[the content of the repeating unit (3)] (mol/mol), is preferably 0.9/1 to 1/0.9, more preferably 0.95/1 to 1/0.95, and still more preferably 0.98/1 to 1/0.98.

It is to be noted that the repeating units (1) to (3) may be each independently contained in the liquid crystal polymer that is used in the present embodiment, where the repeating units (1) to (3) are two or more kinds. In addition, the liquid crystal polymer may have a repeating unit other than the repeating units (1) to (3); however, the content proportion thereof is preferably 0% by mole or more and 10% by mole or less and more preferably 0% by mole or more and 5% by mole or less with respect to the total amount of all repeating units.

The liquid crystal polymer that is used in the present embodiment preferably has a repeating unit in which X and Y are each independently an oxygen atom, as the repeating unit (3). That is, it is preferable to have a repeating unit derived from a predetermined aromatic diol since the melt viscosity tends to decrease, and it is preferable to have only a repeating unit in which X and Y are each an oxygen atom, as the repeating unit (3).

The liquid crystal polymer that is used in the present embodiment is preferably produced by subjecting a raw material monomer corresponding to a repeating unit constituting the liquid crystal polymer to melt-polymerization and subjecting the obtained polymerized substance (hereinafter, may be referred to as a “prepolymer”) to solid phase polymerization. This makes it possible to produce a liquid crystal polymer having a high molecular weight, which has high heat resistance or high hardness and rigidity with good operability. The melt polymerization may be carried out in the presence of a catalyst. Here, examples of this catalyst include metal compounds such as magnesium acetate, stannous acetate, tetrabutyl titanate, lead acetate, sodium acetate, potassium acetate, and antimony trioxide, and nitrogen-containing heterocyclic compounds such as 4-(dimethylamino)pyridine and 1-methylimidazole, where a nitrogen-containing heterocyclic compound is preferably used.

The flowing start temperature of the liquid crystal polymer that is used in the present embodiment is preferably 280° C. or higher, more preferably 280° C. or higher and 400° C. or lower, and still more preferably 280° C. or higher and 380° C. or lower.

As the flowing start temperature of the liquid crystal polymer that is used in the present embodiment becomes higher, the more the heat resistance and the hardness and rigidity of the molded body obtained from the liquid crystal polymer resin composition tend to further improve. On the other hand, when the flowing start temperature of the liquid crystal polymer exceeds 400° C., the melt temperature and the melt viscosity of the liquid crystal polymer tend to increase. As a result, the temperature required for molding the liquid crystal polymer tends to be high.

In the present specification, the flowing start temperature of the liquid crystal polymer is also referred to as a flow temperature or a flowing start, and it is a temperature that serves as a guideline for the molecular weight of the liquid crystal polymer (see “Liquid crystal polymer—Synthesis, molding, and application—” edited by Naoyuki Koide, CMC Publishing Co., Ltd., Jun. 5, 1987, p. 95). The flowing start temperature is a temperature at which a viscosity of 4,800 Pa·s (48,000 poises) is obtained by using a capillary rheometer when a liquid crystal polymer is melted while raising the temperature at a rate of 4° C./min under a load of 9.8 MPa (100 kg/cm²), and pushed out from a nozzle having an inner diameter of 1 mm and a length of 10 mm.

In the liquid crystal polymer resin composition, the content proportion of the component (A) is preferably 60% to 80% by mass, more preferably 61% to 79% by mass, still more preferably 62% to 78% by mass, and particularly preferably 65% to 77% by mass, with respect to 100% by mass of the liquid crystal polymer resin composition.

(B′) Carbon Fiber Having Weight-Average Fiber Length of Less than 150 μm

In the present embodiment, the liquid crystal polymer resin composition comprises the component (B′) “the carbon fiber having a weight-average fiber length of less than 150 μm”, and the content of the component (B′) is 10 to 30 parts by mass with respect to 100 parts by mass of the component (A).

As the carbon fiber in the liquid crystal polymer resin composition, it is possible to use various carbon fibers, for example, polyacrylonitrile (PAN)-based, pitch-based (coal pitch-based or petroleum pitch-based), cellulose-based, and lignin-based carbon fibers. Among these, at least one carbon fiber selected from the group consisting of a PAN-based carbon fiber and a pitch-based carbon fiber is particularly preferable.

The weight-average fiber length of the carbon fibers in the liquid crystal polymer resin composition is not particularly limited as long as it is less than 150 μm.

The weight-average fiber length of the carbon fibers in the liquid crystal polymer resin composition can be determined according to the following procedure. First, a liquid crystal polymer resin composition is heated in an air atmosphere to remove the resin, and an ashing residue containing carbon fibers is obtained. The ashing residue is dispersed in an aqueous solution containing a surfactant and diluted with pure water to obtain a diluted sample solution. Using a particle shape image analyzer, the obtained diluted sample solution is allowed to pass through a flow cell, and carbon fibers moving in the solution are imaged one by one. The obtained image is subjected to a binarization process, a major axis of a circumscribed rectangle of each of 30,000 carbon fibers in the processed image is measured, and the weight-average fiber length of the carbon fibers in the liquid crystal polymer resin composition is determined according to Expression (5).

Lw=ΣLi²/ΣLi (5)

Lw: Weight-average fiber length

Li: Major axis of circumscribed rectangle of i-th carbon fiber

The weight-average fiber length of the carbon fibers in the liquid crystal polymer resin composition is less than 150 μm, and the content of the component (B′) is 10 to 30 parts by mass with respect to 100 parts by mass of the component (A). As a result, while maintaining excellent tape peelability of a molded body obtained by molding the liquid crystal polymer resin composition, the surface resistance value of the molded body obtained by molding the liquid crystal polymer resin composition is easily controlled to a proper surface resistance value in an electrostatic diffusion region of 1.0×10⁵ to 1.0×10¹¹Ω. Since the surface resistance value of the molded body obtained by molding the liquid crystal polymer resin composition can be easily controlled to a proper value of 1.0×10⁵Ω or more while maintaining excellent tape peelability, the weight-average fiber length of the carbon fibers in the liquid crystal polymer resin composition is preferably 146 μm or less, more preferably 142 μm or less, and still more preferably 138 μm or less. Since the surface resistance value of the molded body obtained by molding the liquid crystal polymer resin composition can be easily controlled to a proper value of 1.0×10¹¹Ω or less while maintaining excellent tape peelability, the weight-average fiber length of the carbon fibers in the liquid crystal polymer resin composition is preferably 60 μm or more, more preferably 70 μm or more, and still more preferably 80 μm or more.

The weight-average fiber length of the carbon fibers in the liquid crystal polymer resin composition is preferably 60 μm or more and less than 146 μm, more preferably 70 μm or more and 142 μm or less, still more preferably 80 μm or more and 138 μm or less, and particularly preferably 90 μm or more and 135 μm or less.

The average diameter of the carbon fibers in the liquid crystal polymer resin composition is preferably 3 to 15 μm.

When the average diameter of the carbon fibers is less than 3 μm, the effect as a reinforcing material tends to be small. Further, when the average diameter of the carbon fibers exceeds 15 μm, the moldability is deteriorated, and the appearance of the surface of the molded body tends to be deteriorated.

In the liquid crystal polymer resin composition according to the present embodiment, the content of the component (B′) is 10 to 30 parts by mass with respect to 100 parts by mass of the component (A), where it is preferably 11 to 29 parts by mass, more preferably 12 to 28 parts by mass, and still more preferably 22 to 27.5 parts by Mass.

(C) Carbon Precursor Having Volume Resistivity of 10² to 10¹⁰ Ω·cm

The liquid crystal polymer resin composition according to the present embodiment comprises the component (C) “carbon precursor having a volume resistivity of 10² to 10¹⁰ Ω·cm”, and the content of the component (C) is 5 to 35 parts by mass with respect to 100 parts by mass of the component (A).

The carbon precursor having a volume resistivity of 10² to 10¹⁰ Ω·cm can be obtained by sintering an organic substance in an inert atmosphere at a temperature of 400° C. to 900° C. according to, for example, the method disclosed in Japanese Unexamined Patent Application. First Publication No. 2002-121402 (Patent Document 1). The carbon precursor can be produced by, for example, (i) a method of heating pitch or tar such as petroleum tar, petroleum pitch, coal tar, or coal pitch to carry out aromatization and polycondensation, carrying out oxidization and infusiblization in an oxygen atmosphere as necessary, and then carrying out heating and sintering in an inert atmosphere, (ii) a method of infusiblizing a thermoplastic resin such as polyacrylonitrile or polyvinyl chloride in an oxygen atmosphere and then carrying out heating and sintering in an inert atmosphere, or (iii) a method of subjecting a thermosetting resin such as a phenolic resin or a furan resin to heat curing and then carrying out heating and sintering in an inert atmosphere.

The carbon precursor is a substance having a carbon content proportion of 97% by mass or less, which has not been completely carbonized by this treatment. The carbon content proportion of the carbon precursor is preferably 80% to 97% by mass and more preferably in a range of 85% to 97% by mass. This makes it possible to obtain a carbon precursor having a volume resistivity of 10² to 10¹⁰ Ω·cm, where the volume resistivity is a value in a state where the carbon precursor is not completely carbonized. The volume resistivity of the carbon precursor is preferably 10³ to 10⁹ Ω·cm and more preferably 10⁴ to 10⁸ Ω·cm.

The volume resistivity of the carbon precursor can be measured as follows.

A carbon precursor is subjected to pressurization molding to obtain a plate-shaped molded body. This plate-shaped molded body is subjected to heat treatment at 580° C. in a nitrogen stream for 1 hour to obtain a measurement sample. The volume resistivity of this measurement sample is measured according to JIS K 7194.

When the volume resistivity of the carbon precursor in the liquid crystal polymer resin composition is 10² to 10¹⁰ Ω·cm, and the content of the component (C) is 5 to 35 parts by mass with respect to 100 parts by mass of the component (A), the surface resistance value of the molded body obtained by molding the liquid crystal polymer resin composition is easily controlled to a proper value of 1.0×10⁵ to 1.0×10¹¹Ω while excellent tape peelability of the molded body is maintained.

The surface resistance value of the molded body obtained by molding the liquid crystal polymer resin composition can be measured by using, for example, a resistance-measuring system manufactured by PROSTAT Corporation, USA.

In the liquid crystal polymer resin composition according to the present embodiment, the carbon precursor is used generally in a particle shape or a fiber shape. The average particle diameter of the carbon precursor particles is preferably 1 μm or less. When the average particle diameter of the carbon precursor particles is too large, it is difficult to obtain a molded product having a good appearance when the liquid crystal polymer resin composition is molded. The average particle diameter of the carbon precursor particles is generally 0.1 μm to 1 mm, preferably 1 to 800 μm, and more preferably 5 to 500 μm. In a large number of cases, it is possible to obtain good results when using carbon precursor particles having an average particle diameter of about 5 to 50 μm.

In the liquid crystal polymer resin composition according to the present embodiment, the content of the component (C) is 5 to 35 parts by mass with respect to 100 parts by mass of the component (A), where it is preferably 5 to 32 parts by mass, more preferably 6 to 32 parts by mass, still more preferably 6.5 to 14 parts by mass, and particularly preferably 6.5 to 11 parts by mass.

In the liquid crystal polymer resin composition according to the present embodiment, the content of the total of the component (B′) and the component (C) is 25 to 60 parts by mass with respect to 100 parts by mass of the component (A), where it is preferably 28 to 58 parts by mass, more preferably 28 to 50 parts by mass, and still more preferably 28 to 40 parts by mass.

In the liquid crystal polymer resin composition according to the present embodiment, since the weight-average fiber length of the carbon fibers in the liquid crystal polymer resin composition is less than 150 μm, the volume resistivity of the carbon precursor in the liquid crystal polymer resin composition is 10² to 10¹⁰ Ω·cm, the content of the component (B′) is 10 to 30 parts by mass with respect to 100 parts by mass of the component (A), the content of the component (C) is 5 to 35 parts by mass with respect to 100 parts by mass of the component (A), and the content of the total of the component (B′) and the component (C) is 25 to 60 parts by mass with respect to 100 parts by mass of the component (A), it is possible to mold a molded body having a proper surface resistance value in an electrostatic diffusion region and having excellent tape peelability.

(Other Components)

The liquid crystal polymer resin composition according to the present embodiment may comprise, as necessary, one or more of (D) conductive carbon black, a thermoplastic resin, a filling material, an additive, and the like, in addition to the component (A), the component (B′), and the component (C).

(D) Conductive Carbon Black

The liquid crystal polymer resin composition according to the present embodiment may comprise (D) conductive carbon black.

The conductive carbon black that is used here may be obtained according to any method for producing; however, specific examples thereof include channel black, furnace black, and acetylene black. In addition, the average particle diameter thereof is preferably 30 μm or less from the viewpoint of the dispersibility in the liquid crystal polymer resin composition.

The content of the component (D) is preferably 0 to 20 parts by mass, more preferably 0.5 to 18 parts by mass, and still more preferably 1 to 15 parts by mass with respect to 100 parts by mass of the component (A).

The content of the total of the component (B′), the component (C), and the component (D) is preferably 25 to 60 parts by mass, more preferably 28 to 60 parts by mass, and still more preferably 30 to 50 parts by mass, with respect to 100 parts by mass of the component (A).

In the liquid crystal polymer resin composition according to the present embodiment, since the weight-average fiber length of the carbon fibers in the liquid crystal polymer resin composition is less than 150 μm, the volume resistivity of the carbon precursor in the liquid crystal polymer resin composition is 10² to 10¹⁰ Ω·cm, the content of the component (B′) is 10 to 30 parts by mass with respect to 100 parts by mass of the component (A), the content of the component (C) is 5 to 35 parts by mass with respect to 100 parts by mass of the component (A), the content of the total of the component (B′) and the component (C) is 25 to 60 parts by mass with respect to 100 parts by mass of the component (A), and the content of the total of the component (B′), the component (C), and the component (D) is 25 to 60 parts by mass with respect to 100 parts by mass of the component (A), it is possible to mold a molded body having a proper surface resistance value in an electrostatic diffusion region and having more excellent tape peelability.

Thermoplastic Resin

Examples of the thermoplastic resin other than the liquid crystal polymer contained in the liquid crystal polymer resin composition include thermoplastic resins other than the liquid crystal polymer, such as polypropylene, polyamide, polyester other than the liquid crystal polyester, polysulfone, a polyphenylene sulfide, a polyether ketone, polycarbonate, a polyphenylene ether, and a polyether imide.

The content of the thermoplastic resin other than the liquid crystal polymer may be 0 to 20 parts by mass, 0 to 10 parts by mass, 0 to 5 parts by mass, or 0 parts by mass, with respect to 100 parts by mass of the component (A).

Filling Material

The filling material may include a plate-shaped filling material, a spherical filling material, or another granular filling material. In addition, the filling material may be an inorganic filling material or an organic filling material.

Examples of the plate-like inorganic filling material include talc, mica, graphite, wollastonite, barium sulfate, and calcium carbonate. The mica may be white mica, phlogopite, fluorine phlogopite, or tetrasilicon mica.

Examples of the granular inorganic filling material include silica, alumina, titanium oxide, boron nitride, silicon carbide, and calcium carbonate.

Additive

Examples of additives include an antioxidant, a heat stabilizer, a UV-absorbing agent, an antistatic agent, a surfactant, a flame retardant, and a coloring agent.

The liquid crystal polymer resin composition according to the present embodiment has the following aspects.

“1” A liquid crystal polymer resin composition comprising the following component (A), component (B′), and component (C):

(A) liquid crystal polymer;

(B′) carbon fiber having a weight-average fiber length of less than 150 μm; and

(C) carbon precursor having a volume resistivity of 10² to 10¹⁰ Ω·cm,

in which a content of the component (B′) is 10 to 30 parts by mass with respect to 100 parts by mass of the component (A),

a content of the component (C) is 5 to 35 parts by mass with respect to 100 parts by mass of the component (A), and

a content of a total of the component (B′) and the component (C) is 25 to 60 parts by mass with respect to 100 parts by mass of the component (A).

“2” The liquid crystal polymer resin composition according to “1”, in which the content of the component (B′) is preferably 11 to 29 parts by mass, more preferably 12 to 28 parts by mass, and still more preferably 22 to 27 parts by mass with respect to 100 parts by mass of the component (A).

“3” The liquid crystal polymer resin composition according to “1” or “2”, in which the content of the component (C) is preferably 5 to 32 parts by mass, more preferably 6 to 32 parts by mass, still more preferably 6.5 to 14 parts by mass, and particularly preferably 6.5 to 11 parts by mass, with respect to 100 parts by mass of the component (A).

“4” The liquid crystal polymer resin composition according to any one of “1” to “3”, in which the content of the total of the component (B′) and the component (C) is preferably 26 to 60 parts by mass, more preferably 28 to 50 parts by mass, and still more preferably 28 to 36 parts by mass, with respect to 100 parts by mass of the component (A).

“5” The liquid crystal polymer resin composition according to any one of “1” to “4”, further comprising:

a component (D) conductive carbon black,

in which the content of the total of the component (B′), the component (C), and the component (D) is 25 to 60 parts by mass with respect to 100 parts by mass of the component (A), where it is preferably 25 to 60 parts by mass, more preferably 28 to 60 parts by mass, and still more preferably 30 to 50 parts by mass.

“6” The liquid crystal polymer resin composition according to “5”, in which the content of the component (D) is 0 to 20 parts by mass with respect to 100 parts by mass of the component (A), where it is preferably 0.5 to 18 parts by mass and more preferably 1 to 16 parts by mass.

The liquid crystal polymer resin composition according to the present embodiment can be produced by mixing, for example, the component (A), the component (B′), and the component (C), and as necessary, other components. Alternatively, the liquid crystal polymer resin composition according to the present embodiment can be produced by being subjected to melt kneading as shown below.

<Method for Producing Liquid Crystal Polymer Resin Composition>

The method for producing a liquid crystal polymer resin composition according to the present embodiment is a method for producing a liquid crystal polymer resin composition, the method including:

subjecting the following component (A), component (B), and component (C) to melt kneading:

(A) liquid crystal polymer,

(B) carbon fiber having a weight-average fiber length of less than 3,000 μm, and

(C) carbon precursor having a volume resistivity of 10² to 10¹⁰ Ω·cm,

in which a compounding amount of the component (B) is 10 to 30 parts by mass with respect to 100 parts by mass of the component (A),

a compounding amount of the component (C) is 5 to 35 parts by mass with respect to 100 parts by mass of the component (A), and

a compounding amount of a total of the component (B) and the component (C) is 25 to 60 parts by mass with respect to 100 parts by mass of the component (A).

In the method for producing a liquid crystal polymer resin composition according to the present embodiment, the above-described component (D) conductive carbon black can be further blended, and the above-described other components can be further blended as necessary.

In the method for producing a liquid crystal polymer resin composition according to the present embodiment, the compounding amount of each of the components is the same as the content of each of the above-described components in the obtained liquid crystal polymer resin composition.

That is, in the method for producing a liquid crystal polymer resin composition according to the present embodiment, since the compounding amount of the component (B) is 10 to 30 parts by mass with respect to 100 parts by mass of the component (A), the compounding amount of the component (C) is 5 to 35 parts by mass with respect to 100 parts by mass of the component (A), and the compounding amount of the total of the component (B) and the component (C) is 25 to 60 parts by mass with respect to 100 parts by mass of the component (A), it is possible to mold a molded body having a proper surface resistance value in an electrostatic diffusion region and having excellent tape peelability, from the obtained liquid crystal polymer resin composition.

In the method for producing a liquid crystal polymer resin composition according to the present embodiment, since the compounding amount of the component (B) is 10 to 30 parts by mass with respect to 100 parts by mass of the component (A), the compounding amount of the component (C) is 5 to 35 parts by mass with respect to 100 parts by mass of the component (A), the compounding amount of the total of the component (B) and the component (C) is 25 to 60 parts by mass with respect to 100 parts by mass of the component (A), and the compounding amount of the total of the component (B), the component (C), and the component (D) is 25 to 60 parts by mass with respect to 100 parts by mass of the component (A), it is possible to mold a molded body having a proper surface resistance value in an electrostatic diffusion region and having more excellent tape peelability.

For example, the component (A), the component (B′), and the component (C), and as necessary, other components are mixed and subjected to melt kneading with a twin-screw extruder while carrying out degassing, and the obtained mixture is ejected into a strand shape through a circular nozzle (an ejection port) and subsequently pelletized with a strand cutter, whereby a pellet-shaped (that is, cylinder-shaped) liquid crystal polymer resin composition can be obtained.

It can be understood that the composition and characteristics of the liquid crystal polymer in the pellet-shaped liquid crystal polymer resin composition do not change from the composition and characteristics of the liquid crystal polymer as a raw material.

It can be understood that the volume resistivity of the carbon precursor in the pellet-shaped liquid crystal polymer resin composition does not change from the volume resistivity of the carbon precursor as a raw material.

The weight-average fiber length of the carbon fibers in the pellet-shaped liquid crystal polymer resin composition varies depending on the production conditions of the pellet-shaped liquid crystal polymer resin composition; however, it tends to be shortened approximately by 0% to 95% from the weight-average fiber length of the carbon fiber as a raw material of the component (B).

Since the weight-average fiber length of the carbon fibers in the liquid crystal polymer resin composition can be suitably adjusted, the weight-average fiber length of the carbon fibers of the component (B) is less than 3,000 μm, and is preferably 1.000 μm or less and more preferably 200 μm or less. The weight-average fiber length of the carbon fibers of the component (B) is preferably 60 μm or more, more preferably 100 μm or more, and still more preferably 140 μm or more. The weight-average fiber length of the carbon fibers of the component (B) is preferably 60 μm or more and less than 3,000 μm, more preferably 100 μm or more and 1,000 μm or less, and still more preferably 140 μm or more and 200 μm or less.

The weight-average fiber length of the carbon fibers of the component (B) can be determined according to the following procedure. Carbon fibers of the component (B) are dispersed in an aqueous solution containing a surfactant and diluted with pure water to obtain a diluted sample solution. Using a particle shape image analyzer, the obtained diluted sample solution is allowed to pass through a flow cell, and carbon fibers moving in the solution are imaged one by one. The obtained image is subjected to a binarization process, a major axis of a circumscribed rectangle of each of 30,000 carbon fibers in the processed image is measured, and the weight-average fiber length of the carbon fibers of the component (B) is determined according to Expression (5).

Lw=ΣLi²/ΣLi (5)

Lw: Weight-average fiber length

Li: Major axis of circumscribed rectangle of i-th carbon fiber

However, when the weight-average fiber length of the carbon fibers of the component (B) exceeds 1,000 μm, it can be determined according to the following procedure. The carbon fibers of the component (B) are dispersed in an aqueous solution containing a surfactant to obtain a sample solution. Some of the sample solution is taken out to observe with a microscope, and the lengths of more than 500 carbon fibers are measured, whereby the weight-average fiber length of the carbon fibers of the component (B) is determined according to Expression (5).

When producing a pellet-shaped liquid crystal polymer resin composition using a twin-screw extruder, it is possible to control the weight-average fiber length of the carbon fibers in the pellet-shaped liquid crystal polymer resin composition by changing the screw configuration of the twin-screw extruder even when carbon fibers having the same weight-average fiber length are used as a raw material. When the length of a kneading zone (a kneading part) of the twin-screw extruder is short, the weight-average fiber length of the carbon fibers in the pellet-shaped liquid crystal polymer resin composition tends to be long. The short weight-average fiber length of the carbon fibers in the pellet-shaped liquid crystal polymer resin composition can be achieved by increasing the length of the kneading zone (the kneading part).

The method for producing a liquid crystal polymer resin composition according to the present embodiment has the following aspects.

“101” A method for producing a liquid crystal polymer resin composition, the method including:

subjecting the following component (A), component (B), and component (C) to melt kneading:

(A) liquid crystal polymer,

(B) carbon fiber having a weight-average fiber length of less than 3,000 μm, and

(C) carbon precursor having a volume resistivity of 10² to 10¹⁰ Ω·cm,

in which a compounding amount of the component (B) is 10 to 30 parts by mass with respect to 100 parts by mass of the component (A),

a compounding amount of the component (C) is 5 to 35 parts by mass with respect to 100 parts by mass of the component (A), and

a compounding amount of a total of the component (B) and the component (C) is 25 to 60 parts by mass with respect to 100 parts by mass of the component (A).

“102” The method for producing a liquid crystal polymer resin composition according to “101”, in which the compounding amount of the component (B) is preferably 11 to 29 parts by mass, more preferably 12 to 28 parts by mass, and still more preferably 22 to 27.5 parts by mass with respect to 100 parts by mass of the component (A).

“103” The method for producing a liquid crystal polymer resin composition according to “101” or “102”, in which the compounding amount of the component (C) is preferably 5 to 32 parts by mass, more preferably 6 to 32 parts by mass, still more preferably 6.5 to 14 parts by mass, and particularly preferably 6.5 to 11 parts by mass, with respect to 100 parts by mass of the component (A).

“104” The method for producing a liquid crystal polymer resin composition according to any one of “101” to “103”, in which the compounding amount of the total of the component (B) and the component (C) is preferably 28 to 60 parts by mass, more preferably 28 to 55 parts by mass, and still more preferably 28.5 to 50 parts by mass, with respect to 100 parts by mass of the component (A).

“105” The method for producing a liquid crystal polymer resin composition according to any one of “101” to “104”, further comprising:

a component (D) conductive carbon black,

in which the compounding amount of the total of the component (B), the component (C), and the component (D) is 25 to 60 parts by mass with respect to 100 parts by mass of the component (A), where it is preferably 25 to 60 parts by mass, more preferably 28 to 60 parts by mass, and still more preferably 30 to 50 parts by mass.

“106” The method for producing a liquid crystal polymer resin composition according to “105”, in which the compounding amount of the component (D) is 0 to 20 parts by mass with respect to 100 parts by mass of the component (A), where it is preferably 0.5 to 18 parts by mass and more preferably 1 to 16 parts by mass.

(Molded Body)

From the liquid crystal polymer resin composition according to the present embodiment, it is possible to obtain a molded body having a proper surface resistance value in an electrostatic diffusion region of 1.0×10⁵ to 1.0×10¹¹Ω according to a known molding method. The method of molding a molded body from the liquid crystal polymer resin composition is preferably a melting molding method, and examples thereof include an injection molding method, an extrusion molding method such as a T-die method or an inflation method, a compression molding method, a blow molding method, a vacuum molding method, and a press molding. Among them, an injection molding method is preferable.

For example, when a liquid crystal polymer resin composition is used as a molding material and molding is carried out by an injection molding method, a known injection molding machine is used to melt the liquid crystal polymer resin composition, and the melted liquid crystal polymer resin composition is injected into a mold to carrying out molding.

Examples of the known injection molding machine include hydraulic horizontal molding machines such as UH1000 and PS40E5ASE, manufactured by NISSEI PLASTIC INDUSTRIAL Co., Ltd.

The cylinder temperature of the injection molding machine is appropriately determined according to the kind of the liquid crystal polymer, and is preferably set to a temperature higher by 10° C. to 80° C. than the flowing start temperature of the liquid crystal polymer to be used, for example, 320° C. to 400° C.

From the viewpoint of the cooling rate and the productivity of the liquid crystal polymer resin composition, the temperature of the mold is preferably set in a range of room temperature (for example, 23° C.) to 180° C.

It may be understood that the composition and characteristics of the liquid crystal polymer in the liquid crystal polymer resin composition of the molded body do not change from the composition and characteristics of the liquid crystal polymer as a raw material.

It may be understood that the volume resistivity of the carbon precursor in the liquid crystal polymer resin composition of the molded body does not change from the volume resistivity of the carbon precursor as a raw material.

It may be understood that the weight-average fiber length of the carbon fibers in the liquid crystal polymer resin composition of the molded body obtained by the injection molding from the pellet-shaped liquid crystal polymer resin composition does not change from the weight-average fiber length of the carbon fibers in the pellet-shaped liquid crystal polymer resin composition.

The molded body obtained by molding the liquid crystal polymer resin composition according to the present embodiment exhibits a proper surface resistance value in an electrostatic diffusion region and has excellent tape peelability, and thus it can be suitably applied to a wide range of fields where static electricity control, antistaticity, electromagnetic wave shielding, dust adsorption prevention, or the like is required. For example, the molded body is suitably applicable to a semiconductor conveyance carrier.

<Semiconductor Conveyance Carrier>

The semiconductor conveyance carrier according to the present embodiment has a main body part made of the liquid crystal polymer resin composition.

The molded body obtained from the liquid crystal polymer resin composition exhibits a proper surface resistance value in an electrostatic diffusion region of 1.0×10⁵ to 1.0×10¹¹Ω. Furthermore, due to the fact that a molded body having excellent tape peelability can be molded, the liquid crystal polymer resin composition is suitably applicable to a semiconductor conveyance carrier.

Examples of the semiconductor conveyance carrier include a wafer carrier, a wafer cassette, an IC chip tray, an IC chip carrier, an IC conveyance tube, a storage tray, a conveyance device component, an MR head carrier, a GMR head carrier, and a liquid crystal panel carrier.

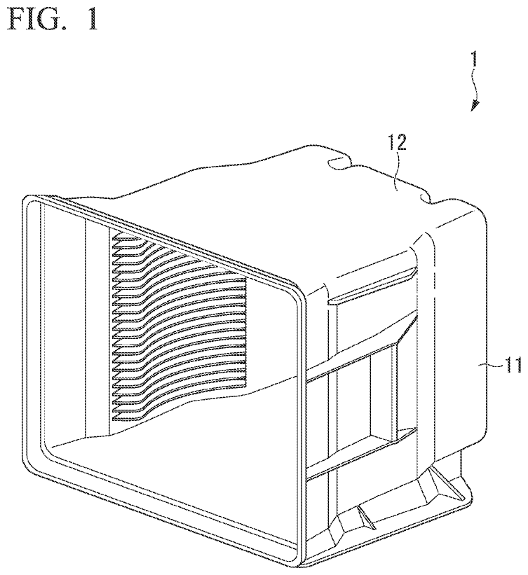

FIG. 1 is a perspective view schematically showing an example of a semiconductor conveyance carrier according to the present embodiment. A semiconductor conveyance carrier 1 according to the present embodiment has a main body part 11 made of the liquid crystal polymer resin composition and a tape sticking part 12 at a visible position on the outside of the main body part 11. The main body part 11 is obtained by molding the liquid crystal polymer resin composition. The main body part 11 is designed to be capable of conveying or storing semiconductor parts such as a wafer, an IC, an MR head, a GMR head, and a liquid crystal panel, or semiconductor products.

The tape sticking part 12 of the semiconductor conveyance carrier 1 exhibits a proper surface resistance value in an electrostatic diffusion region of 1.0×10⁵ to 1.0×10¹¹Ω, and has excellent tape peelability. As a result, the semiconductor conveyance carrier 1 has excellent antistatic and dust adsorption-preventing properties, and can be repeatedly used by sticking a strongly adhesive tagging tape for display on the tape sticking part 12 and peeling it off.

The surface resistance value of the tape sticking part 12 of the semiconductor conveyance carrier 1 is 1.0×10⁵ to 1.0×10¹¹Ω, and is preferably 4×10⁵ to 4×10¹⁰Ω and more preferably 1.0×10⁶ to 1.0×10¹⁰Ω.

### EXAMPLES

Hereinafter, the present invention will be described in more detail with reference to specific examples. However, the present invention is not limited to Examples shown below.

### (A) Liquid Crystal Polymer

### Production of Liquid Crystal Polymer

### Production Example 1: Production of Liquid Crystal Polymer (L1)

994.5 g (7.2 mol) of p-hydroxybenzoic acid, 299.0 g (1.8 mol) of terephthalic acid, 99.7 g (0.6 mol) of isophthalic acid, 446.9 g (2.4 mol) of 4,4′-dihydroxybiphenyl, and 1,347.6 g (13.2 mol) of anhydrous acetic acid were placed in a reactor equipped with a stirrer, a torque meter, a nitrogen gas introduction tube, a thermometer, and a reflux condenser, the gas in the reactor was replaced with nitrogen gas, 0.18 g of 1-methylimidazole was subsequently added thereto, the temperature was raised from room temperature to 150° C. over 30 minutes while carrying out stirring under a nitrogen gas stream, and reflux was carried out at 150° C. for 30 minutes.

Next, 2.4 g of 1-methylimidazole was added thereto, the temperature was raised from 150° C. to 320° C. over 2 hours and 50 minutes while distilling off the acetic acid produced as a byproduct and the unreacted anhydrous acetic acid, and the contents were taken out from the reactor at a time when an increase in torque was observed, followed by cooling to room temperature, whereby a solid prepolymer was obtained.

Next, the prepolymer was pulverized using a pulverizer, and under a nitrogen atmosphere, the temperature of the obtained pulverized product was raised from room temperature to 250° C. over 1 hour, subsequently raised from 250° C. to 295° C. over 5 hours, and held at 295° C. for 3 hours, whereby solid phase polymerization was carried out.

The obtained solid phase polymer was cooled to room temperature to obtain a powdery liquid crystal polymer (L1). The flowing start temperature of the obtained liquid crystal polymer (L1) was 327° C.

### (B) Carbon Fiber

The following commercially available carbon fiber filler was used as a raw material.

(B-1) PANTEX35-MF150, manufactured by Zoltek Corporation, USA (weight-average fiber length: 150 μm, diameter: 7 μm)

(B-2) DIALEAD (registered trade name) K233HE, manufactured by Mitsubishi Chemical Corporation (weight-average fiber length: 6.0 mm, diameter: 11 μm)

<Measurement of Weight-average Fiber Length of Carbon Fiber as Raw Material>

To 50 mL of pure water, 0.3 g of the carbon fiber filler as a raw material ((B-1) PANTEX35-MF150, manufactured by Zoltek Corporation, USA) was added, and a surfactant (0.5% by volume of an aqueous solution of micro-90 (manufactured by Sigma-Aldrich Japan)) was added thereto in order to improve dispersibility, whereby a mixed solution was obtained. The obtained mixed solution was ultrasonically dispersed for 5 minutes to obtain a sample solution in which carbon fibers were uniformly dispersed in the solution. Next, 5 mL of the obtained sample solution was sampled, placed in a sample cup, and diluted 5-fold with pure water to obtain a diluted sample solution. Using a particle shape image analyzer (“PITA3” manufactured by SEISHIN ENTERPRISE Co., Ltd.), the obtained diluted sample solution was allowed to pass through a flow cell, and carbon fibers moving in the solution were imaged one by one. It is to be noted that in this measurement method, the time when the number of total carbon fibers, integrated from the start of the measurement, reaches 30,000 is defined as the measurement termination point. The obtained image was subjected to a binarization process, a major axis of a circumscribed rectangle of each of the carbon fibers in the processed image was measured, and the weight-average fiber length of the carbon fibers of the raw material was determined according to Expression (5). As a result of the determination, the weight-average fiber length of the carbon fibers of (B-1) as a raw material was 150 μm.

Lw=ΣLi²/ΣLi (5)

Lw: Weight-average fiber length

Li: Major axis of circumscribed rectangle of i-th carbon fiber

Number of fibers measured: 30,000

To 50 ml of pure water, 0.3 g of (B-2) DIALEAD (registered trade name) K233HE, manufactured by Mitsubishi Chemical Corporation was added, and a surfactant (0.5% by volume of an aqueous solution of micro-90 (manufactured by Sigma-Aldrich Japan)) was added thereto in order to improve dispersibility, whereby a mixed solution was obtained. The obtained mixed solution was ultrasonically dispersed for 5 minutes to obtain a sample solution in which carbon fibers were uniformly dispersed in the solution. Then, some of the sample solution was taken out, and an image of the fiber was captured at a magnification of 10 to 20 times using a microscope (VH-Z25, manufactured by KEYENCE CORPORATION). The fiber length of the captured image was measured as follows using image processing software (WinROOF 2018, manufactured by MITANI CORPORATION).

(Method of Measuring Fiber Length)

(a) A captured image is subjected to monochrome pixel conversion processing.

(b) A binarization process is carried out so that only the imaged carbon fiber can be colored.

(c) The fiber length is measured using the needle shape separation function of the image processing software.

(d) The fiber length of the fiber that could not be subjected to the binarization in (c) or the curved fiber is measured by multi-point measurement, and the fiber in contact with the edge of the image is not measured.

However, when n >500, that is, when the number of fibers measured does not exceed 500, an additional microscopic image is captured, and measurement is carried out until n exceeds 500.

Using the obtained measurement results, the weight-average fiber length of the carbon fibers as a raw material was determined according to Expression (5). As a result of the determination, the weight-average fiber length of the carbon fibers of (B-2) as a raw material was 6.0 mm.

Lw=ΣLi²/ΣLi (5)

Lw: Weight-average fiber length

Li: Major axis of circumscribed rectangle of i-th carbon fiber

### (C) Carbon Precursor Having Volume Resistivity of 10² to 10¹⁰ Ω·cm

Krefine (registered trade name) KH-CP (volume resistivity: 3×10⁷ Ω·cm, average particle diameter: 22 μm) purchased from Kureha Corporation was used as a raw material.

<Measurement of Volume Resistivity of Carbon Precursor>

A cylindrical mold having a cross-sectional area of 80 cm² was filled with 15 g of a carbon precursor (Krefine (registered trade name) KH-CP), which was subsequently molded at a pressure of 200 MPa to obtain a disk-shaped molded body. This disk-shaped molded body was subjected to heat treatment at 580° C. in a nitrogen stream for 1 hour to obtain a measurement sample. The volume resistivity of this measurement sample was measured according to JIS K 7194. As a result of the measurement, the volume resistivity was 3×10⁷ Ω·cm.

### (D) Conductive Carbon Black

Ketjen Black (registered trade name) (EC-300J (manufactured by Lion Corporation), primary particle diameter: 39.5 nm) was used as a raw material.

<Method for Producing Liquid Crystal Polymer Resin Composition>

In producing the pellet-shaped liquid crystal polymer resin composition, a twin-screw extruder (manufactured by Ikegai Corp. “PCM30-HS”) having a main raw material feeder in the upstream part and a side feeder in the downstream part was used.

### Example 1

According to the compounding ratio shown in Table 1, the liquid crystal polymer (L1) and the carbon precursor (Krefine (registered trade name) KH-CP) were supplied from the main raw material feeder of the twin-screw extruder, and the carbon fiber filler ((B-1) PANTEX35-MF150) was supplied from the side feeder. Each raw material was subjected to melt kneading at a cylinder temperature of 340° C. and a screw rotation speed of 150 rpm, and a strand-shaped liquid crystal polymer resin composition was ejected at an extrusion rate of 300 kg/h through a circular nozzle (an ejection port) having a diameter of 3 mm.

Then, it was cooled and pelletized to prepare a cylinder-shaped (length 3 mm, that is, pellet-shaped) liquid crystal polymer resin composition of Example 1.

### Examples 2 to 5 and 10 and Comparative Examples 1 to 3, 6, and 8

Similarly, a pellet-shaped liquid crystal polymer resin composition of each of Examples 2 to 5, and 10 and Comparative Examples 1 to 3, 6, and 8 was prepared according to the compounding ratio shown in Table 1.

### Example 6

According to the compounding ratio shown in Table 1, a raw material of each of the above-described (A) liquid crystal polymer, (C) carbon precursor having a volume resistivity of 10² to 10¹⁰ Ω·cm, and (D) conductive carbon black (conductive CB) was supplied from the main raw material feeder, and a raw material of (B) carbon fiber was supplied from the side feeder. Each raw material was subjected to melt kneading at a cylinder temperature of 340° C. and a screw rotation speed of 150 rpm, and a strand-shaped liquid crystal polymer resin composition was ejected at an extrusion rate of 300 kg/h through a circular nozzle (an ejection port) having a diameter of 3 mm.

Then, it was cooled and pelletized to prepare a cylinder-shaped (length 3 mm, that is, pellet-shaped) liquid crystal polymer resin composition of Example 1.

### Examples 7 to 9 and Comparative Examples 4, 5, 7, and 9

Similarly, a pellet-shaped liquid crystal polymer resin composition of each of Examples 7 to 9 and Comparative Examples 4, 5, 7, and 9 was prepared according to the compounding ratio shown in Table 1.

### Comparative Example 10

According to the compounding ratio shown in Table 1, a pellet-shaped liquid crystal polymer resin composition of Comparative Examples 10 was prepared in the same manner as in Example 1, except that the carbon fiber filler of Example 1 was changed to (B-2) DIALEAD (registered trade name) K233HE, manufactured by Mitsubishi Chemical Corporation.

<Measurement of Weight-average Fiber Length of the carbon fibers in Resin Composition>

5 g of the pellet-shaped liquid crystal polymer resin composition of each of Examples and Comparative Examples was heated in an air atmosphere at 600° C. for 4 hours in a muffle furnace (“FP410”, manufactured by Yamato Scientific Co., Ltd.) to remove the resin, whereby an ashing residue containing carbon fibers was obtained, 0.3 g of the ashing residue was added to 50 ml of pure water, and a surfactant (0.5% by volume of an aqueous solution of micro-90 (manufactured by Sigma-Aldrich Japan)) was added thereto in order to improve dispersibility, whereby a mixed solution was obtained. The obtained mixed solution was ultrasonically dispersed for 5 minutes to obtain a sample solution in which carbon fibers contained in the ashing residue were uniformly dispersed in the solution. Next, 5 mL of the obtained sample solution was sampled, placed in a sample cup, and diluted 5-fold with pure water to obtain a diluted sample solution. Using a particle shape image analyzer (“PITA3” manufactured by SEISHIN ENTERPRISE Co., Ltd.), the obtained diluted sample solution was allowed to pass through a flow cell, and carbon fibers moving in the solution were imaged one by one. It is to be noted that since ones having a major axis of a circumscribed rectangle of less than 30 μm were from the carbon precursor or the ashing residue of the conductive carbon black, the setting was carried out in this measuring method so that ones having the major axis of a circumscribed rectangle of less than 30 μm could be excluded at the time of image capture, and the time when the number of total carbon fibers, integrated from the start of the measurement, reached 30,000 was defined as the measurement termination point. The obtained image was subjected to a binarization process, a major axis of a circumscribed rectangle of each of the carbon fibers in the processed image was measured, and the weight-average fiber length of the carbon fibers in the liquid crystal polymer resin composition having a pellet shape was determined according to Expression (5). The results are shown in Table 1.

Lw=ΣLi²/ΣLi (5)

Lw: Weight-average fiber length

Li: Major axis of circumscribed rectangle of i-th carbon fiber

Number of fibers measured: 30,000

<Preparation of Injection Molding Test Piece>

A pellet-shaped liquid crystal polymer resin composition of each of Examples 1 to 10 and Comparative Examples 1 to 10 was put into an injection molding machine UH1000 (NISSEI PLASTIC INDUSTRIAL Co., Ltd.) having a cylinder temperature of 340° C., and injected into a mold having a mold temperature of 120° C. at an injection rate of 20 mm/s, a screw rotation speed of 100 rpm, a holding pressure of 50 MPa. and a back pressure of 3 MPa, thereby preparing an injection molding test piece (surface roughness Ra=3 μm) of 64 mm×64 mm×3 mmt.

<Measurement of Surface Resistance Value of Injection Molding Test Piece>

The surface resistance value of the injection molding test piece of 64 mm×64 mm×3 mmt, made of the resin composition of each of Examples 1 to 10 and Comparative Examples 1 to 10, was measured by using a resistance-measuring system (PRS-801) and a sensor electrode (PRF-912), manufactured by PROSTAT CORPORATION, USA. The results are shown in Table 1.

<Tape Peelability Test>

An electroplating tape (470 Electroplating Tape S10258, manufactured by 3M) having a width of 25 μm was affixed to the injection molding test piece of 64 mm×64 mm×3 mint, made of the resin composition of Example 1, according to JIS Z0237 in the molding direction (MD) of the test piece by using a pressing roller with a mass of 2.0 kg and peeled off after being allowed to stand for 24 hours, and then the presence or absence of peeling of the skin layer of the liquid crystal polymer on the surface of the injection molding test piece was observed. The operation of affixing the above-described electroplating tape in the same manner to the same position in the molding direction (MD) of the test piece, peeling it off after allowing it to stand for 24 hours, and then observing the presence or absence of peeling of the skin layer of the liquid crystal polymer on the surface of the injection molding test piece was repeated 4 times, whereby the operation was carried out 5 times in total.

The operation of affixing the above-described electroplating tape in the same manner to the same position of the same injection molding test piece in a direction (TD) perpendicular to the MD of the test piece, peeling it off after allowing it to stand for 24 hours, and then observing the presence or absence of peeling of the skin layer of the liquid crystal polymer on the surface of the injection molding test piece was repeated 5 times.

Regarding ten peeling tests, evaluation was carried out according to the following determination criteria for the tape peelability.

Determination Criteria for Tape Peelability

Excellent (E): When where the number of skin layers without peeling is 9 or more and 10 or less in N=10

Good (G): When where the number of skin layers without peeling was 5 or more and 9 or less in N=10

Failure (F): When where the number of skin layers without peeling was less than 5 in N=10

The injection molding test piece of 64 mm×64 mm×3 mmt, made of the resin composition of each of Examples 2 to 10 and Comparative Examples 1 to 10, was also evaluated in the same manner. The results are shown in Table 1.

TABLE 1

| | Component | | | Component | | Total of | | | |
|---|---|---|---|---|---|---|---|---|---|
| | (A) liquid | Component | Component | (D) | Total of | components | | | |
| | crystal | (B) carbon | (C) carbon | conductive | components | (B), (C), | Surface | | Average |
| | polymer | fiber | precursor | CB | (B) and (C) | and (D) | resistance | | fiber |
| | (part by | (part by | (part by | (part by | (part by | (part by | value | Tape | length |
| | mass) | mass) | mass) | mass) | mass) | mass) | (Ω) | peelability | (μm) |
| Example 1 | 100.0 | 14.3 | 28.6 | 0.0 | 42.9 | 42.9 | 2.1 × 10⁹ | G | 93 |
| Example 2 | 100.0 | 17.2 | 20.7 | 0.0 | 37.9 | 37.9 | 6.2 × 10⁸ | G | 120 |
| Example 3 | 100.0 | 25.0 | 31.3 | 0.0 | 56.3 | 56.3 | 1.2 × 10⁶ | G | 124 |
| Example 4 | 100.0 | 28.0 | 32.0 | 0.0 | 60.0 | 60.0 | 1.5 × 10⁸ | G | 85 |
| Example 5 | 100.0 | 26.7 | 6.7 | 0.0 | 33.3 | 33.3 | 8.0 × 10⁸ | G | 114 |
| Example 6 | 100.0 | 22.2 | 6.5 | 2.0 | 28.8 | 30.7 | 3.4 × 10⁸ | E | 126 |
| Example 7 | 100.0 | 25.3 | 10.3 | 1.4 | 35.6 | 37.0 | 1.5 × 10⁸ | E | 114 |
| Example 8 | 100.0 | 27.0 | 6.8 | 1.4 | 33.8 | 35.1 | 6.4 × 10⁷ | E | 108 |
| Example 9 | 100.0 | 24.3 | 7.1 | 11.4 | 31.4 | 42.9 | 1.5 × 10⁷ | E | 94 |
| Example 10 | 100.0 | 21.4 | 21.4 | 0.0 | 42.9 | 42.9 | 4.9 × 10⁸ | G | 105 |
| Comparative | 100.0 | 6.3 | 18.8 | 0.0 | 25.0 | 25.0 | 2.1 × 10¹² | G | 73 |
| Example 1 | | | | | | | | | |
| Comparative | 100.0 | 24.0 | 36.0 | 0.0 | 60.0 | 60.0 | 1.9 × 10⁷ | F | 93 |
| Example 2 | | | | | | | | | |
| Comparative | 100.0 | 25.0 | 41.7 | 0.0 | 66.7 | 66.7 | 2.1 × 10⁵ | F | 128 |
| Example 3 | | | | | | | | | |
| Comparative | 100.0 | 18.8 | 0.0 | 6.3 | 18.8 | 25.0 | 0.3 × 10⁵ | F | 98 |
| Example 4 | | | | | | | | | |
| Comparative | 100.0 | 11.8 | 0.0 | 5.9 | 11.8 | 17.6 | 2.7 × 10¹² | E | 113 |
| Example 5 | | | | | | | | | |
| Comparative | 100.0 | 33.3 | 33.3 | 0.0 | 66.7 | 66.7 | 3.9 × 10⁵ | F | 118 |
| Example 6 | | | | | | | | | |
| Comparative | 100.0 | 31.9 | 11.6 | 1.4 | 43.5 | 44.9 | 3.0 × 10⁴ | E | 114 |
| Example 7 | | | | | | | | | |
| Comparative | 100.0 | 21.4 | 21.4 | 0.0 | 42.9 | 42.9 | 7.2 × 10⁴ | G | 150 |
| Example 8 | | | | | | | | | |
| Comparative | 100.0 | 28.3 | 8.3 | 30.0 | 36.7 | 66.7 | 1.1 × 10⁵ | F | 108 |
| Example 9 | | | | | | | | | |
| Comparative | 100.0 | 30.0 | 25.0 | 0.0 | 55.0 | 55.0 | 2.8 × 10⁵ | G | 199 |
| Example 10 | | | | | | | | | |

As can be understood from the results in Table 1, it has been shown that from the liquid crystal polymer resin composition of each of Examples 1 to 10 in which the content of the component (B′) is 10 to 30 parts by mass with respect to 100 parts by mass of the component (A), the content of the component (C) is 5 to 35 parts by mass with respect to 100 parts by mass of the component (A), and the content of a total of the component (B′) and the component (C) is 25 to 60 parts by mass with respect to 100 parts by mass of the component (A), it is possible to mold a molded body having a proper surface resistance value in an electrostatic diffusion region of 1.0×10⁵ to 1.0×10¹¹Ω and excellent tape peelability.

On the other hand, as shown in Table 1, although the molded body made of the liquid crystal polymer resin composition of each of Comparative Examples 1, 5, 7 to 8, and 10 has excellent tape peelability, it does not exhibit a proper surface resistance value in an electrostatic diffusion region of 1.0×10⁵ to 1.0×10¹¹Ω. Although the molded body made of the liquid crystal polymer resin composition of each of Comparative Examples 2 to 4, 6, and 9 exhibits a proper surface resistance value in an electrostatic diffusion region of 1.0×10⁵ to 1.0×10¹¹Ω, it has a problem in the tape peelability.

As a result, the liquid crystal polymer resin composition according to the present invention can be suitably applied to a semiconductor conveyance carrier.

### REFERENCE SIGNS LIST

1: Semiconductor conveyance carrier
11: Main body part
12: Tape sticking part

1. A liquid crystal polymer resin composition comprising the following component (A), component (B′), and component (C):
(A) liquid crystal polymer;
(B′) carbon fiber having a weight-average fiber length of less than 150 μm; and
(C) carbon precursor having a volume resistivity of 10² to 10¹⁰ Ω·cm,
wherein a content of the component (B′) is 10 to 30 parts by mass with respect to 100 parts by mass of the component (A),
a content of the component (C) is 5 to 35 parts by mass with respect to 100 parts by mass of the component (A), and
a content of a total of the component (B′) and the component (C) is 25 to 60 parts by mass with respect to 100 parts by mass of the component (A).

2. The liquid crystal polymer resin composition according to claim 1, further comprising:
a component (D) conductive carbon black,
wherein a content of a total of the component (B′), the component (C), and the component (D) is 25 to 60 parts by mass with respect to 100 parts by mass of the component (A).

3. A semiconductor conveyance carrier comprising a main body part made of the liquid crystal polymer resin composition according to claim 1.

4. A method for producing a liquid crystal polymer resin composition, the method comprising:
subjecting the following component (A), component (B), and component (C) to melt kneading:
(A) liquid crystal polymer,
(B) carbon fiber having a weight-average fiber length of less than 3,000 μm, and
(C) carbon precursor having a volume resistivity of 10² to 10¹⁰ Ω·cm,
wherein a compounding amount of the component (B) is 10 to 30 parts by mass with respect to 100 parts by mass of the component (A),
a compounding amount of the component (C) is 5 to 35 parts by mass with respect to 100 parts by mass of the component (A), and
a compounding amount of a total of the component (B) and the component (C) is 25 to 60 parts by mass with respect to 100 parts by mass of the component (A).
